(19) United States
(12) Patent Application Publication
(10) Pub. No.: US 2026/0223286 A1
(43) Pub. Date: Jul. 30, 2026

(54) STRETCHABLE CIRCUIT SUBSTRATE AND STRETCHABLE DEVICE

(71) Applicant: TDK CORPORATION, Tokyo (JP)

(72) Inventors: Hajime AZUMA, Tokyo (JP); Kazutaka TAMAKI, Tokyo (JP); Yumiko OZAKI, Tokyo (JP)

(73) Assignee: TDK CORPORATION, Tokyo (JP)

(21) Appl. No.: 19/143,094

(22) PCT Filed: Dec. 25, 2023
(86) PCT No.: PCT/JP2023/046333

§ 371 Date: Jun. 25, 2025

(30) Foreign Application Priority Data
Dec. 28, 2022 (JP) 2022-212027

(51) Int. Cl. H05K 1/02; H05K 1/181; H05K 1/189

(52) U.S. Cl. CPC H05K 1/0283; H05K 1/181; H05K 1/189; H05K 2201/10037

(57) ABSTRACT

This stretchable circuit substrate includes: a stretchable substrate; a non-stretchable portion connected to a part of the outer circumferential portion of a first surface of the stretchable substrate; a first electrical wiring disposed on the first surface of the stretchable substrate; and a second electrical wiring disposed on the non-stretchable portion, in which the first electrical wiring and the second electrical wiring are connected, and the stretchable substrate and the non-stretchable portion are connected by a conductive adhesive containing a stretchable resin.

### TECHNICAL FIELD

The present invention relates to a stretchable circuit substrate and a stretchable device.

Priority is claimed on Japanese Patent Application No. 2022-212027, filed Dec. 28, 2022, the content of which is incorporated herein by reference.

### BACKGROUND ART

In recent years, along with the development of flexible sensors, wearable devices capable of managing physical condition have been attracting attention.

Wearable devices are expected to have a wide range of applications in the fields of sports science and healthcare, where they are designed to measure and monitor specific parts of the body such as those directly attached to the skin or those built into clothing. Since human skin is repeatedly stretched and contracted on a daily basis, it is desirable for a wearable device to be stretchable in response to the object on which it is worn if stress-free wearability is desired for the wearable device. In addition, it is desirable that the wearable device have a strength at a certain level or higher against stress generated during its bending and rolling, assuming its handling or human movement. Devices with such a characteristic are referred to as stretchable devices in the present specification, with their use not limited to wearable devices.

Patent Document 1 describes a wiring board including: a substrate including a first substrate having stretchability and a second substrate which is located outside a side surface of the first substrate and has an elastic modulus greater than that of the first substrate; and a conductor including wiring located on a first surface side of the first substrate. In addition, electronic components that are connected to the conductor and disposed on the first surface side of the first substrate are described.

Stretchable devices are assumed to include electrodes, wiring, devices, electronic components, thin-film sensors, and the like within stretchable elements, and it is necessary for them to maintain their quality even in a use environment where stretching and contracting are repeated. However, it is difficult to realize such stretchable devices with polyimide sheets used in conventional thin-film resin boards. For this reason, it is assumed that resins, such as urethane resins, silicone resins, acrylic resins, epoxy resins, polycarbonates, polystyrene, and polyolefins, compatible with stretchability will be used as main constituent materials for elements and electrodes in stretchable devices. Among these, it is thought that a stretchable film which is a cured product of a composition containing a (meth)acrylate compound with a siloxane bond, a (meth)acrylate compound, other than the (meth)acrylate compound, that has a urethane bond, and an organic solvent with a boiling point in a range of 115° C. to 200° C. at atmospheric pressure and in which the (meth)acrylate compound with a siloxane bond is unevenly distributed on the film surface would have excellent stretchability and strength comparable to those of polyurethanes, and the film surface would have excellent water repellency comparable to that of silicones (refer to Patent Document 2).

### CITATION LIST

### Patent Document

Patent Document 1: Japanese Unexamined Patent Application, First Public ation No. 2021-57507
Patent Document 2: Japanese Unexamined Patent Application, First Public ation No. 2017-206626

### SUMMARY OF INVENTION

### Technical Problem

In the wiring board of Patent Document 1, the conductor including wiring is formed on the first substrate having stretchability, and when the electronic components are disposed on the wiring board, as described in Patent Document 1, the electronic components connected to the conductor are also arranged on the first substrate. In a configuration in which an adhesive seal that can be adhered is provided on the rear side of this wiring board, the electronic components mounted on the first substrate having stretchability are likely to be damaged when peeled off, and there is a particularly high risk of damage to the electronic components when the attachment and peeling off are repeated.

In the case of the resin sheet (resin film) made mainly of a cured product of a resin composition as described in Patent Document 2, if the curing reaction does not proceed uniformly, there is a problem that variations in composition and degree of curing may occur in the resin sheet, resulting in the sheet not having desired stretchability, strength, and aging degradation resistance characteristics. In addition, to realize stretchable devices, wiring with high conductivity and stretchability as well as a small change in conductivity during stretching and contracting is desired.

The present invention provides a stretchable circuit substrate and a stretchable device in which the risk of damage to mounted electronic components and the like is reduced when the attachment and peeling off are repeated.

In addition, the present invention provides a stretchable circuit substrate and a stretchable device that are equipped with electrical wiring that is highly conductive and highly stretchable and that exhibits minimal change in conductivity when the attachment and peeling off are repeated.

### Solution to Problem

The present invention provides the following means to solve the above-described problems.

Aspect 1 of the present invention is a stretchable circuit substrate including: a stretchable substrate; a non-stretchable portion connected to at least a part of the outer circumferential portion of a first surface of the stretchable substrate or a side surface portion of the stretchable substrate; a first electrical wiring having stretchability and disposed on the first surface of the stretchable substrate; and a second electrical wiring disposed on the non-stretchable portion, in which at least a part of the first electrical wiring and the second electrical wiring are connected.

In aspect 2 of the present invention, in the stretchable circuit substrate according to aspect 1, the stretchable substrate and the non-stretchable portion are connected by a conductive adhesive containing a stretchable resin.

In aspect 3 of the present invention, in the stretchable circuit substrate according to aspect 1 or 2, a part of the non-stretchable portion has a tab portion protruding upward.

In aspect 4 of the present invention, in the stretchable circuit substrate according to any one of aspects 1 to 3, the non-stretchable portion is disposed on the outer circumferential portion of the stretchable substrate.

In aspect 5 of the present invention, in the stretchable circuit substrate according to any one of aspects 1 to 3, the non-stretchable portion is connected to the side surface portion of the stretchable substrate, and the bottom surface of the non-stretchable portion and the bottom surface of the stretchable substrate are disposed flush with each other.

In aspect 6 of the present invention, in the stretchable circuit substrate according to any one of aspects 1 to 5, a seal for attaching to an adherend is provided on the surface on the rear side of the first surface of the stretchable circuit substrate.

Aspect 7 of the present invention is a stretchable device including: an electronic component disposed on the non-stretchable portion included in the stretchable circuit substrate according to any one of aspects 1 to 6.

Aspect 8 of the present invention is a stretchable device including: a module disposed on the non-stretchable portion included in the stretchable circuit substrate according to any one of aspects 1 to 6.

Aspect 9 of the present invention is a stretchable device including: a battery disposed on the non-stretchable portion included in the stretchable circuit substrate according to any one of aspects 1 to 6.

### Advantageous Effects of Invention

According to the present invention, it is possible to provide a stretchable circuit substrate in which the risk of damage to a mounted electronic component and the like is reduced when the attachment and peeling off are repeated.

### BRIEF DESCRIPTION OF DRAWINGS

FIG. 1A is a plan view conceptually showing a stretchable circuit substrate according to the present embodiment, and is a plan view showing a stretchable circuit substrate according to a first mode.

FIG. 1B is a plan view conceptually showing a stretchable circuit substrate according to the present embodiment, and is a plan view showing a stretchable circuit substrate according to a second mode.

FIG. 1C is a plan view conceptually showing a stretchable circuit substrate according to the present embodiment, and is a plan view showing a stretchable circuit substrate according to a third mode.

FIG. 2 is a cross-sectional view of the stretchable circuit substrate shown in FIG. 1.

FIG. 3A is a conceptual view showing how a stretchable substrate having no non-stretchable portion begins to be peeled off from an adherend to which it is attached.

FIG. 3B is a conceptual view showing how the stretchable substrate is further peeled off from the adherend after the state shown in FIG. 3A.

FIG. 3C is a view for conceptually explaining the operational effect of a stretchable substrate having a non-stretchable portion (the stretchable circuit substrate according to the present embodiment), and is a conceptual view showing a state in which the stretchable circuit substrate is attached to an adherend.

FIG. 3D is a conceptual view showing how the stretchable circuit substrate begins to be peeled off from the adherend after the state shown in FIG. 3C.

FIG. 4 is a cross-sectional view conceptually showing a stretchable circuit substrate according to another embodiment.

FIG. 5A is a plan view conceptually showing a stretchable circuit substrate according to still another embodiment.

FIG. 5B is a cross-sectional view conceptually showing a stretchable circuit substrate according to still another embodiment.

### DESCRIPTION OF EMBODIMENTS

Hereinafter, the present invention will be described in detail with appropriate reference to the drawings. In the drawings used in the following description, a part that becomes a feature is sometimes enlarged for convenience in order to allow the feature to be easily understood, and the dimensional ratios of each constituent element and the like are sometimes different from the actual ones. The materials, dimensions, and the like exemplified in the following description are merely examples, and the present invention is not limited thereto and can be implemented by being appropriately modified within the range in which the effect of the present invention is exhibited.

### [Stretchable Circuit Substrate]

A stretchable circuit substrate according to the present embodiment includes: a stretchable substrate; a non-stretchable portion connected to at least a part of the outer circumferential portion or the side surface portion of the stretchable substrate; a first electrical wiring having stretchability and disposed on the stretchable substrate; and a second electrical wiring disposed on the non-stretchable portion, in which at least a part of the first electrical wiring and the second electrical wiring are connected. The stretchable substrate and the non-stretchable portion are preferably connected by a conductive adhesive containing a stretchable resin.

In the present specification, the term “non-stretchable portion” refers to a portion made of an insulating material having a Young's modulus of 0.6 kPa or more.

As long as the Young's modulus is 0.6 kPa or more, the material is not particularly limited, and well-known insulating materials may be used. Representative insulating materials that can be used include resin materials, and examples of such materials include resins such as polyethylene terephthalate (PET), polyethylene naphthalate (PEN), polymethyl methacrylate (PMMA), polyimide (PI), polyamide, polyacrylic acid (PAA), polyvinyl alcohol (PVA), polyvinyl chloride (PVC), polypropylene, polysiloxane, epoxy, glass epoxy, and silicon wafers. These resins may be used alone or in combination of two or more thereof. Details will be described below.

As the material of the non-stretchable portion, for example, PMMA of about 2.5 GPa, PI of about 3 GPa, or a PET film of about 4 GPa can be used. These values of

Young's modulus are a guideline since the Young's modulus depends on the method for preparing the material.

On the other hand, in the present specification, the “stretchable substrate” is made of an insulating material having a Young's modulus that is ½ or less than that of the insulating material constituting the “non-stretchable portion”, preferably an insulating material having a Young's modulus that is ⅕ or less, more preferably an insulating material having a Young's modulus that is 1/10 or less, still more preferably an insulating material having a Young's modulus that is 1/20 or less, even more preferably an insulating material having a Young's modulus that is 1/50 or less, and even more preferably an insulating material having a Young's modulus that is 1/100 or less. A typical insulating material that can be used is a resin material, and examples of such materials include resins such as epoxy resins, urethane resins, and methacrylic acid resins. These resins may be used alone or in combination of two or more thereof. Details will be described below.

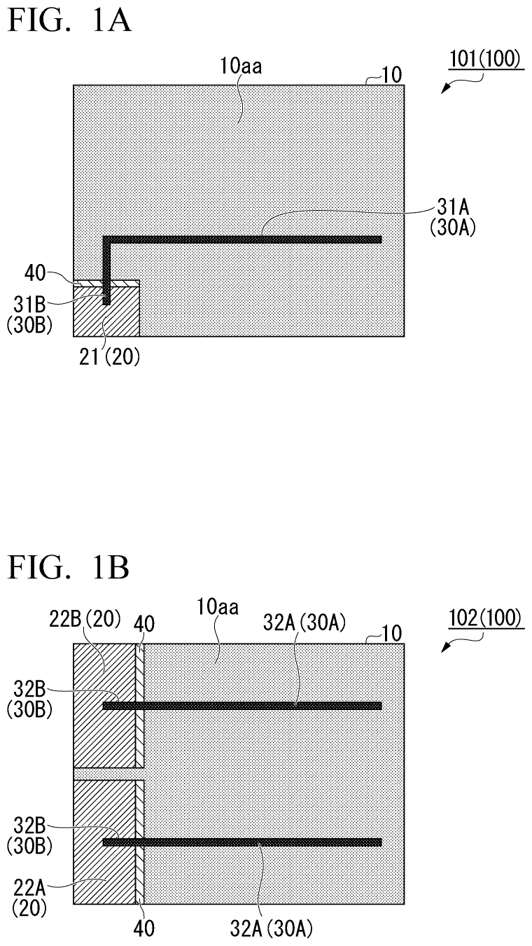

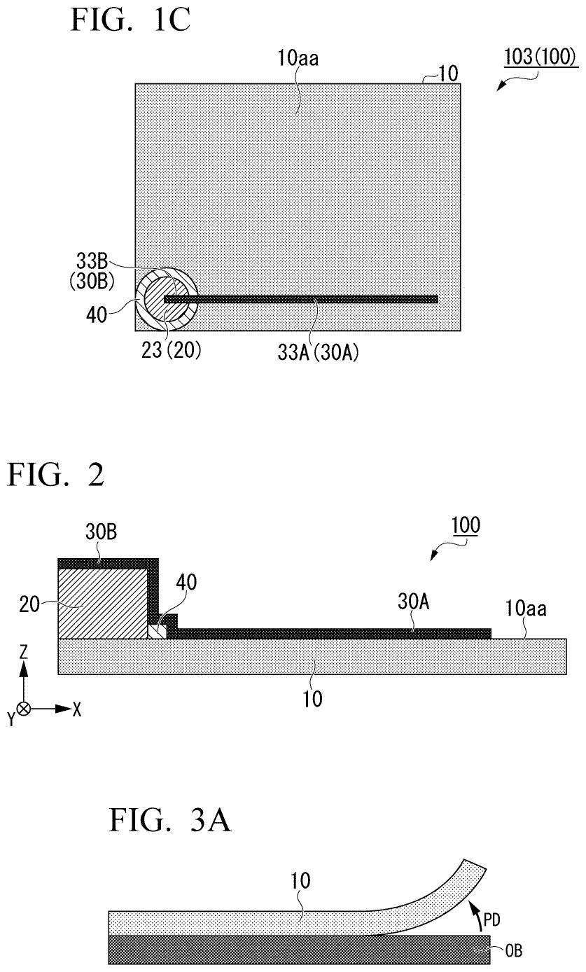

FIG. 1 shows plan views conceptually showing stretchable circuit substrates according to the present embodiment.

A stretchable circuit substrate 101 (100) shown in FIG. 1A includes: a stretchable substrate 10; a non-stretchable portion 21 (20) connected to a part of the outer circumferential portion of a first surface 10aa of the stretchable substrate 10; a first electrical wiring 31A (30A) disposed on the first surface 10aa of the stretchable substrate 10; and a second electrical wiring 31B (30B) disposed on the non-stretchable portion, in which the first electrical wiring 31A (30A) and the second electrical wiring 31B (30B) are connected, and the stretchable substrate 10 and the non-stretchable portion 21 (20) are connected by a conductive adhesive 40 containing a stretchable resin (hereinafter sometimes referred to as a “stretchable resin-containing conductive adhesive”).

In the stretchable circuit substrate 101 (100) shown in FIG. 1A, the non-stretchable portion 21 (20) is disposed close to one of the four corners of the outer circumferential portion of the rectangular stretchable substrate 10 in a plan view in the Z-direction.

In addition, in the stretchable circuit substrate 101 (100) shown in FIG. 1A, the first electrical wiring 31A (30A) disposed on the stretchable substrate 10 and the second electrical wiring 31B (30B) arranged on the non-stretchable portion are connected via the stretchable resin-containing conductive adhesive 40.

In addition, in the stretchable circuit substrate 101 (100) shown in FIG. 1A, the stretchable resin-containing conductive adhesive 40 is disposed on one of the four sides of the rectangular non-stretchable portion 21 (20) in a plan view in the Z-direction, but this arrangement is merely an example, and is not particularly limited as long as it functions to connect the stretchable substrate 10 and the non-stretchable portion 21 (20).

A stretchable circuit substrate 102 (100) shown in FIG. 1B includes: a stretchable substrate 10; a non-stretchable portion 22A (20) and a non-stretchable portion 22B (20) connected to a part of the outer circumferential portion of the stretchable substrate 10; first electrical wirings 32A (30A) disposed on the stretchable substrate 10;

and second electrical wirings 32B (30B) disposed on the non-stretchable portions, in which the first electrical wirings 32A (30A) are respectively connected to the second electrical wirings 32B (30B), and the stretchable substrate 10 is connected to the non-stretchable portions 21 (20) by conductive adhesives 40 containing a stretchable resin.

In the stretchable circuit substrate 102 (100) shown in FIG. 1B, the non-stretchable portion 22A (20) and the non-stretchable portion 22B (20) are spaced apart from each other and disposed close to one of the four sides of the outer circumferential portion of the rectangular stretchable substrate 10.

In addition, in the stretchable circuit substrate 102 (100) shown in FIG. 1B, the first electrical wirings 32A (30A) arranged on the stretchable substrate 10 are respectively connected to the second electrical wirings 32B (30B) arranged on the non-stretchable portions via the stretchable resin-containing conductive adhesives 40.

In addition, in the stretchable circuit substrate 102 (100) shown in FIG. 1B, the stretchable resin-containing conductive adhesives 40 are arranged along the inner side of one of the four sides of the rectangular non-stretchable portion 22A (20) and the non-stretchable portion 22B (20) in a plan view in the Z-direction, but this arrangement is merely an example, and is not particularly limited as long as it functions to connect the stretchable substrate 10 to the non-stretchable portion 22A (20) and the non-stretchable portion 22B (20).

A stretchable circuit substrate 103 (100) shown in FIG. 1C includes: a stretchable substrate 10; a non-stretchable portion 23 (20) connected to a part of the outer circumferential portion of the stretchable substrate 10; a first electrical wiring 33A (30A) disposed on the stretchable substrate 10; and a second electrical wiring 33B (30B) disposed on the non-stretchable portion, in which the first electrical wiring 33A (30A) and the second electrical wiring 33B (30B) are connected, and the stretchable substrate and the non-stretchable portion 23 (20) are connected by a conductive adhesive 40 containing a stretchable resin.

In the stretchable circuit substrate 103 (100) shown in FIG. 1C, the non-stretchable portion 23 (20) is disposed close to one of the four corners of the outer circumferential portion of the rectangular stretchable substrate 10 in a plan view in the Z-direction.

In addition, in the stretchable circuit substrate 103 (100) shown in FIG. 1C, the first electrical wiring 33A (30A) disposed on the stretchable substrate 10 and the second electrical wiring 33B (30B) disposed on the non-stretchable portion are connected via the stretchable resin-containing conductive adhesive 40.

In addition, in the stretchable circuit substrate 103 (100) shown in FIG. 1C, the stretchable resin-containing conductive adhesive 40 is disposed along the entire circumference of the circular non-stretchable portion 23 (20) in a plan view in the Z-direction, but this arrangement is merely an example, and is not particularly limited as long as it functions to connect the stretchable substrate 10 and the non-stretchable portion 23 (20).

In the stretchable circuit substrates 100 (101, 102, 103) shown in FIGS. 1A to 1C, the non-stretchable portions 20 (21, 22A, 22B, 23) are disposed close to a part of the outer circumferential portions of the respective rectangular stretchable substrates in a plan view in the Z-direction, specifically close to one of the four sides or one of the four corners thereof. The non-stretchable portions may also be spaced apart from each other and disposed close to two, three, or four of the four sides, or some may be joined, or they may be spaced apart from each other and disposed close to two, three, or four of the four corners. In addition, some of the non-stretchable portions 20 (21, 22A, 22B, 23) may be disposed close to some of the four sides and some close to some of the four corners.

Furthermore, the non-stretchable portions 20 (21, 22A, 22B, 23) may be disposed in any manner as long as they are located on a part of the outer circumferential portion of the rectangular stretchable substrate in a plan view in the Z-direction. When the stretchable circuit substrates 100 are used by being attached to an adherend (for example, skin or clothing), the non-stretchable portions 20 may be disposed over the entire outer circumferential portion of the stretchable substrate 10 or over the entire circumference.

The width of the outer circumferential portion of the stretchable substrate 10 where the non-stretchable portion 20 is disposed can be, for example, about 5 mm to 20 mm, but is not limited to this width.

FIG. 2 is a cross-sectional view of the stretchable circuit substrate 100 shown in FIGS. 1A to 1C. The cross-sectional view of the stretchable circuit substrate 100 shown in FIG. 2 is taken along a cross section along the first electrical wiring 30A and the second electrical wiring 30B.

As shown in FIG. 2, the non-stretchable portion 20 is disposed on the outer circumferential portion of the stretchable substrate 10.

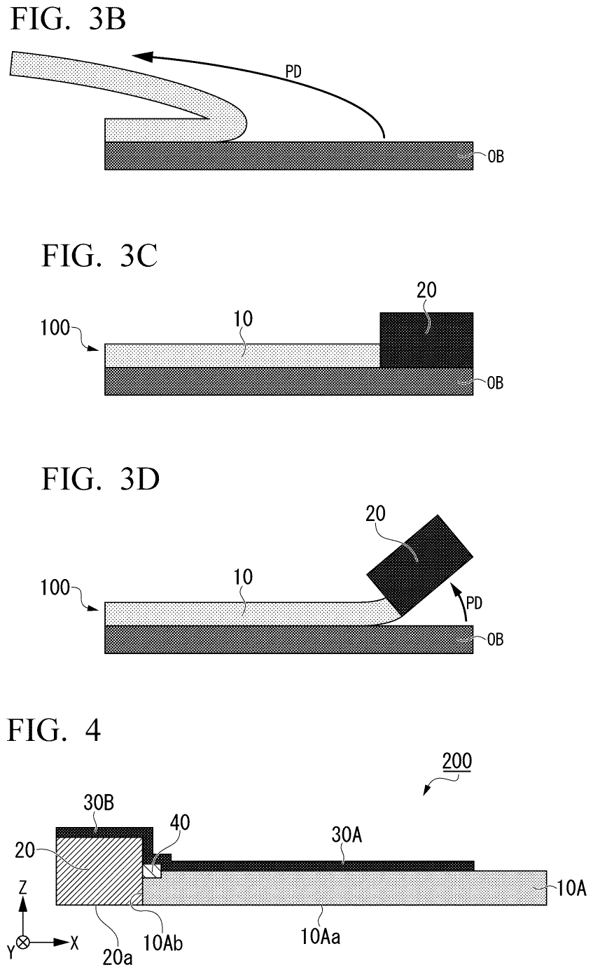

FIGS. 3A to 3D show views for conceptually illustrating the operational effect of the stretchable circuit substrate according to the present embodiment.

FIGS. 3A and 3B are views showing how an end portion of a stretchable substrate 10 is pulled and peeled off from an adherend (for example, skin or clothing) OB to which the stretchable substrate 10 is attached. The reference numeral PD indicates the peeling direction.

FIGS. 3C and 3D are views showing how a non-stretchable portion 20 disposed on the outer circumferential portion of a stretchable substrate 10 is pulled and peeled off from an adherend (for example, skin or clothing) OB to which the stretchable circuit substrate 100 (with a configuration having a non-stretchable portion on the outer circumferential portion of the stretchable substrate) according to the present embodiment is attached. The reference numeral PD indicates the peeling direction.

In FIGS. 3A and 3B, when the stretchable substrate is attached to the adherend, if the adhesiveness is high, a strong peeling power (peeling force) is initially required during peeling off. This is because the soft, stretchable substrate stretches along with the peeling off. In contrast, in FIGS. 3C and 3D, if the stretchable substrate has a portion that does not stretch (non-stretchable portion) on its outer circumferential portion, the non-stretchable portion does not stretch when it is pulled and peeled off, and therefore it can be peeled off with less peeling power (peeling force) than in FIGS. 3A and 3B.

In the stretchable circuit substrate according to the present embodiment, the non-stretchable portion may be configured to be connected to the side surface portion of the stretchable substrate.

A stretchable circuit substrate 200 shown in FIG. 4 includes: a stretchable substrate 10A; a non-stretchable portion 20 connected to a part of a side surface portion 10Ab of the stretchable substrate 10A; a first electrical wiring 30A disposed on the stretchable substrate 10A; and a second electrical wiring 30B disposed on the non-stretchable portion, in which the first electrical wiring 30A and the second electrical wiring 30B are connected, and the stretchable substrate 10A and the non-stretchable portion 20 are connected by a stretchable resin-containing conductive adhesive 40. In addition, this is a case where a bottom surface 20a of the non-stretchable portion 20 and a bottom surface 10Aa of the stretchable substrate 10A are disposed substantially flush with each other.

In FIG. 4, the members denoted by the same reference numerals as those previously described in the drawings indicate members having the same functions.

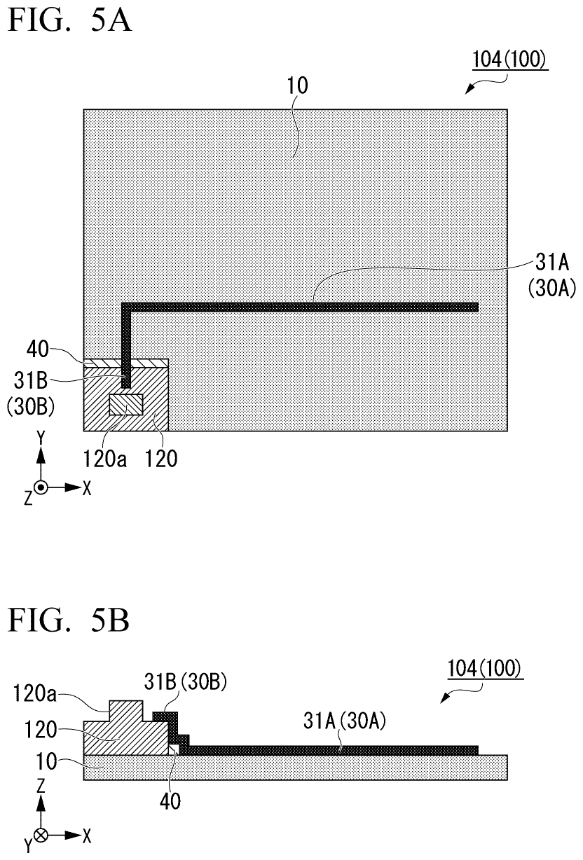

A non-stretchable portion 120 shown in FIGS. 5A and 5B is a case where it has a tab portion 120a protruding upward. The cross-sectional view of a stretchable circuit substrate 104 (100) shown in FIG. 5B is a cross-sectional view taken along a cross section along the first electrical wiring 30A and the second electrical wiring 30B in the plan view of the stretchable circuit substrate of FIG. 5A.

By gripping and pulling the tab portion 120a protruding upward from a part of the non-stretchable portion 120, the stretchable circuit substrate 104 can be more easily peeled off from an adherend (for example, skin or clothing).

The non-stretchable portion 20 of the stretchable circuit substrate 200 shown in FIG. 4 may be configured to have a tab portion protruding upward.

### <Stretchable Substrate>

As described above, the stretchable substrate 10 is an insulating material having a Young's modulus that is 1/10 or less than that of the insulating material constituting a non-stretchable portion, preferably an insulating material having a Young's modulus that is 1/50 or less, and more preferably an insulating material having a Young's modulus that is \vec{1}/100 or less.

As the material used in the stretchable substrate 10, a stretchable resin is preferable. The stretchable resin is not particularly limited, and a well-known stretchable resin can be used as the stretchable resin. Examples thereof include epoxy resins, urethane resins, urea resins, polyurethane urea resins, methacrylic acid resins, polyacrylic resins, silicone resins, diene resins, polyester resins, polyether resins, polyamide resins, and polystyrene resins.

A resin sheet-like stretchable resin substrate made of a stretchable resin (hereinafter sometimes referred to as a “resin sheet”) may be used as the stretchable substrate 10. In addition, a plurality of resin sheets may be laminated to prepare a stretchable resin substrate, which may be used as the stretchable substrate 10.

Hereinafter, a case where the stretchable substrate 10 is made of a stretchable resin material will be mainly described.

The resin used in the stretchable substrate 10 is preferably soluble in any one or more solvents selected from N,N-dimethylacetamide (DMAc), methyl ethyl ketone (MEK), N,N-dimethylformamide (DMF), diethylene glycol monobutyl ether, diethylene glycol monobutyl ether acetate (BCA), diethylene glycol monoethyl ether acetate, diethylene glycol monomethyl ether acetate, acetone, ethanol, methanol, ethyl lactate, butyl lactate, toluene, isopropyl alcohol, isobutyl alcohol, ethyl acetate, and butyl acetate.

The stretchable substrate 10 can be formed by applying and solidifying a resin composition containing a solvent and the resin used in the above-described stretchable substrate 10.

Among the above-described resins, a urethane resin that can be molded by simply applying and drying a resin composition without a curing reaction is preferable.

This is because, with resins that require a curing reaction, if the curing reaction does not proceed uniformly, variations in composition and degree of curing may occur in resin sheets, resulting in resins that do not have desired stretchability, strength, and aging degradation resistance characteristics.

In addition, when a urethane resin is used, it is preferable that the resin component have a siloxane bond. This is because in this case, the resin composition has moderate water repellency, which inhibits hydrolysis of urethane bonds.

Hereinafter, the characteristics of the stretchable substrate 10 will be described while giving a specific example of a resin composition for producing the stretchable substrate 10 made of a stretchable resin material.

As the specific example thereof, there can be mentioned a resin composition containing a resin component (in the present specification, sometimes referred to as “resin component (II)”) having a urethane bond and a group represented by General Formulae (11), (21), or (31) below.

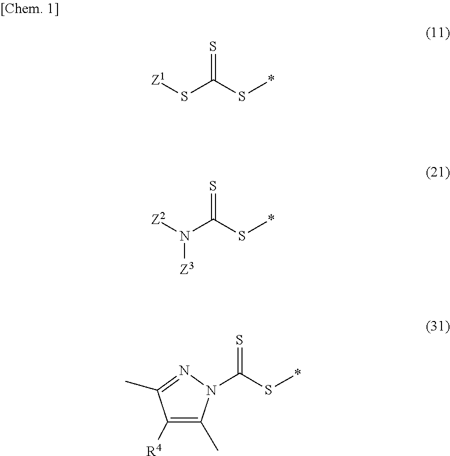

(In the formula, Z¹ is an alkyl group, and one or more hydrogen atoms in the alkyl group may be substituted with a cyano group, a carboxy group, or a methoxycarbonyl group, and two or more of the substituents may be the same as or different from each other. Z² is an alkyl group. Z³ is an aryl group. R⁴ is a hydrogen atom or a halogen atom. A bond marked with a sign * is formed at a bonding destination in the group represented by General Formulae (11), (21), or (31) above.)

The resin component (II) contained in this resin composition is highly flexible because it has a urethane bond.

In addition, the resin component (II) is obtained through a polymerization reaction using a resin having a urethane bond and a polymerizable unsaturated bond and a RAFT agent for performing reversible addition fragmentation chain transfer polymerization (abbreviated as “RAFT polymerization” in the present specification) from which the group represented by General Formulae (11), (21), or (31) above is derived. By conducting the polymerization reaction in this way, gelation of the resin during polymerization in the process of forming a cross-linked structure is avoided, and resin components with the desired degree of polymerization and cross-linked state are obtained. In other words, the resin component (II) having the group represented by General

Formulae (11), (21), or (31) above has a small variation in terms of the degree of polymerization and the cross-linked state.

In addition, the resin component (II) may have a siloxane bond, in which case the resin composition has moderate water repellency, which inhibits hydrolysis of urethane bonds in the resin component (II). Such a resin component (II) is obtained through a further polymerization reaction using a resin having a siloxane bond and a polymerizable unsaturated bond.

The method for producing the resin component (II) in which the RAFT polymerization is performed will be described separately in detail.

The resin having a urethane bond and a polymerizable unsaturated bond used in the production of the resin component (II) is an oligomer and may be referred to as “resin (a).”

In addition, the resin having a siloxane bond and a polymerizable unsaturated bond used in the production of the resin component (II) is an oligomer and may be referred to as “resin (b)” in the present embodiment.

The resin component (II) is a polymer formed through polymerization of resins (a) at their polymerizable unsaturated bonds. When the resin (b) is used, the resin component (II) is a polymer formed through polymerization of the resin (a) and the resin (b) at their polymerizable unsaturated bonds.

When the resin (b) is used, the resin component (II) preferably has both urethane and siloxane bonds in one molecule thereof.

The resin (a) is not particularly limited as long as it has a urethane bond and a polymerizable unsaturated bond.

Examples of the resin (a) include those having a (meth)acryloyl group as a group having a urethane bond and a polymerizable unsaturated bond, and more specific examples thereof include urethane (meth)acrylate.

In the present specification, “(meth)acrylate” is a concept that encompasses both “acrylate” and “methacrylate.” The same applies to terms similar to (meth)acrylate. For example, “(meth)acryloyl group” is a concept that encompasses both “acryloyl group” and “methacryloyl group.”

The resin (b) is not particularly limited as long as it has a siloxane bond and a polymerizable unsaturated bond.

Examples of the resin (b) include various well-known silicone resins having a (meth)acryloyl group as a group having a polymerizable unsaturated bond, and more specific examples thereof include a modified polydialkylsiloxane in which a (meth)acryloyl group is bound to a single terminal or both terminals of polydialkylsiloxane such as polydimethylsiloxane.

The resin component (II) has high solubility in solvents due to its composition. Therefore, the resin composition containing the resin component (II) also has high solubility in solvents.

Such a resin composition having high solubility can easily form a resin composition layer through printing on an object to be applied, for example, through various printing methods. This resin composition layer can then be solidified through drying, without curing, to produce a layer (resin layer, resin sheet) similar to the resin sheets. Such a technique is suitable for forming electrodes or wiring using the resin composition containing conductive components.

Such a resin composition having high solubility is used to form a stretchable resin sheet, and a stretchable device composed of this resin sheet has the great advantage of suppressing damage during its stretching and contracting.

Factors that can cause damage to normal stretchable devices during stretching and contracting, from the viewpoint of materials, include (i) interface delamination and structural defects such as voids caused by contraction due to heat or curing reactions, (ii) uneven hardness caused by uneven composition, and (iii) degradation of materials over time caused by light exposure, oxidation, and the like.

Therefore, structural defects such as voids, and interface delamination, uneven composition, and degradation of materials over time can be suppressed, thereby preventing damage to the stretchable devices during stretching and contracting.

Although molding by thermal melting and cross-linking by thermosetting or photocuring reactions are commonly used to process stretchable substrates, there is a concern that the reliability of the stretchable devices will be lowered if even micromachining is considered due to the reasons (i) to (iii). In contrast, for example, if there is a resin that can be molded only through applying and drying a resin composition in response to a lamination process, it is expected that favorable results can be obtained.

For the stretchable substrate 10, the resin composition of the specific example can be solidified through drying to obtain a resin sheet-like stretchable resin substrate (hereinafter, sometimes referred to as a “resin sheet”). A plurality of resin sheets may be laminated to prepare a stretchable resin substrate.

The resin sheet has favorable stretchability because it contains the resin component (II) as its main component. When the resin (b) is used, the resin sheet further has moderate water repellency, which suppresses degradation over time caused by hydrolysis. The resin sheet with such characteristics is particularly suitable for constructing various types of stretchable devices including wearable devices.

The resin sheet can be formed simply by solidifying the resin composition through drying, as described above, without any curing reaction. Therefore, it does not have the defects associated with performing a curing reaction.

For example, a photocuring reaction is significantly difficult to uniformly cure materials that do not transmit ultraviolet light. For example, when the periphery of a mounted device or an electronic component is irradiated with ultraviolet light, the degree of curing may vary in some areas in a photocurable resin sheet due to variations in ultraviolet light transmission, and the resin sheet is easily damaged in areas with low cross-linking density. In addition, non-cross-linked areas are easily degraded by oxidation.

On the other hand, a thermosetting reaction easily causes contraction differences in the resin sheet due to heat distribution during curing. When such contraction differences occur, different constituent materials among devices, sealants, and the like are easily delaminated at these interfaces. In addition, if areas with different degrees of curing are created in the resin sheet due to heat distribution, the sheet will be easily degraded due to repeated stretching and contracting.

Furthermore, in both cases of photocuring and thermosetting reactions, it is difficult for the reactions to progress uniformly in the resin sheet. In such cases, variations in composition and degree of curing occur in the resin sheet, and the cured resin sheet does not have desired stretchability and strength. In addition, because a curing agent is incorporated, degradation over time due to heat or light easily occurs. In contrast, the resin sheet obtained by solidifying the resin composition of the specific example through drying does not have such defects.

The resin sheet can be produced without a curing reaction by, for example, applying the resin composition to a desired section and solidifying it through drying.

The resin composition can be applied, for example, through well-known methods using various coaters, wire bars, or the like, or through various printing methods including inkjet printing methods.

The drying temperature of the resin composition during the production of the resin sheet is preferably 25° C. to 150° C. and more preferably 25° C. to 120° C. When the drying temperature is 25° C. or higher, it is possible to more efficiently produce a resin sheet. When the drying temperature is 150° C. or lower, the drying temperature is suppressed from becoming excessively high, deformation of a release sheet and damage to the resin sheet are less likely to occur, and deterioration of the resin sheet is suppressed.

The drying time of the resin composition during the production of the resin sheet may be set appropriately according to the drying temperature, but is preferably 10 minutes to 120 minutes and more preferably 30 minutes to 90 minutes. When the drying time is within these ranges, resin sheets with favorable characteristics can be efficiently produced.

Completion of solidification of the resin composition through drying (formation of the resin sheet) can be confirmed, for example, by the fact that no clear change in mass of the resin composition being subjected to drying can be observed.

The elongation of the stretchable resin substrate can be appropriately set according to the elongation required for the stretchable circuit substrate. The elongation can be adjusted, for example, by increasing the amount of stretchable resin to increase the elongation. In addition, the elongation can be adjusted by increasing the mol % of bonds with high elongation in the resin. For example, the elongation of the stretchable resin substrate can be increased by increasing the proportion of urethane bonds in the resin.

The thickness of the stretchable resin substrate is not particularly limited, but can be, for example, 10 μm to 5,000 μm.

### <Non-Stretchable Portion>

The non-stretchable portion 20 is made of an insulating material having a Young's modulus of 0.6 kPa or more. In addition, in relation to the material of the stretchable substrate 10, the non-stretchable portion 20 is made of an insulating material having a Young's modulus that is at least twice that of the stretchable substrate 10, preferably an insulating material having a Young's modulus that is at least five times, more preferably an insulating material having a Young's modulus that is at least ten times, still more preferably an insulating material having a Young's modulus that is at least twenty times, even more preferably an insulating material having a Young's modulus that is at least fifty times, and even more preferably an insulating material having a Young's modulus that is at least hundred times.

The non-stretchable portion 20 is not particularly limited as long as it has a Young's modulus of 0.6 kPa or more, and well-known insulating materials may be used.

Typical insulating materials that can be used are resin materials, and examples of such materials include resins such as polyethylene terephthalate (PET), polyethylene naphthalate (PEN), polymethyl methacrylate (PMMA), and polyimide (PI). These resins may be used alone or in combination of two or more thereof.

### <First Electrical Wiring Having Stretchability>

The first electrical wiring 30A having stretchability can be formed using a stretchable resin (resin having stretchability) containing a metal powder. Hereinafter, the first electrical wiring having stretchability is sometimes referred to as “stretchable electrical wiring.”

When a stretchable resin containing a metal powder is used as the first electrical wiring 30A having stretchability, a known stretchable resin can be used. Examples thereof include urethane resins, acrylic resins, epoxy resins, urea resins, polyurethane urea resins, methacrylic acid resins, polyacrylic resins, silicone resins, diene resins, polyester resins, polyether resins, polyamide resins, polystyrene resins, and polyimide resins. These may be used alone or in combination of two or more thereof.

The above-described resins are preferably soluble in any one or more kinds of solvents selected from diethylene glycol monobutyl ether acetate (BCA), butyl carbitol

(BC), ethyl cyanoacrylate (ECA), a-terpineol, diethylene glycol monobutyl ether, and diethylene glycol monoethyl ether acetate.

It is preferable that the stretchable electrical wiring 30A have high conductivity and high stretchability, and that its change in conductivity during stretching and contracting be minimal.

A stretchable electrical wiring 30A of a first aspect can be formed by applying and solidifying a resin composition containing a resin used, a metal powder, and a solvent.

Among the above-described resins, it is preferable to use a drying-curable resin that can be molded and solidified by only applying and drying the resin composition without a curing reaction. Examples of drying-curable resins include urethane resins. In this case, the stretchable electrical wiring 30A according to the first aspect can be called drying-curable stretchable electrical wiring.

This is because, with resins that require a curing reaction, if the curing reaction does not proceed uniformly, variations in composition and degree of curing may occur in stretchable electrical wiring, resulting in resins that do not have desired stretchability, strength, and aging degradation resistance characteristics.

In addition, when a urethane resin is used, it is preferable that the resin component have a siloxane bond. This is because in this case, the resin composition has moderate water repellency, which inhibits hydrolysis of urethane bonds.

The percentage of the resin in the stretchable electrical wiring 30A of the first aspect is 8 wt % to 20 wt %.

The stretchable electrical wiring 30A of the first aspect is stretchable electrical wiring with a small change in conductivity during stretching and contracting, but the percentage of the resin is 8 wt % or more to ensure high stretchability (high elongation at break) as a precondition for this. On the other hand, the stretchable electrical wiring 30A of the first aspect is stretchable electrical wiring with high conductivity before and during stretching and contracting, but the percentage of the resin is set to 20 wt % or less to ensure high conductivity (low resistivity).

The percentage of the resin in the stretchable electrical wiring 30A is preferably 10 wt % or more. The percentage of the resin in the stretchable electrical wiring 30A is preferably 18 wt % or less.

When a urethane resin is contained in the resin in the stretchable electrical wiring 30A of the first aspect, the percentage of urethane bonds in the resin is preferably 15 wt % or more, and more preferably 17 wt % or more.

The percentage of urethane bonds in the resin can be calculated, for example, by calculating the peak surface area corresponding to the urethane bonds in the C¹³ nuclear magnetic resonance (NMR) spectrum.

In addition, the elongation at break may be low in experimental examples with a high percentage of urethane bonds in the resin, which will be described below. The reason for this is not clear at present, but based on the experimental examples, the percentage of urethane bonds in the resin is preferably 30 wt % or less, more preferably 25 wt % or less, and still more preferably 22 mol % or less.

### (Metal Powder)

Metal powders are not particularly limited, and those known as metal powders can be used. Examples thereof include a silver (Ag) powder, carbon (C), a copper (Cu) powder, a palladium (Pd) powder, a gold (Au) powder, and a platinum (Pt) powder. Among these, a silver powder or an alloy powder mainly composed of silver is preferable because of its low resistance. Here, the alloy powder mainly composed of silver means that more than 50 wt % of the powder is silver, and the percentage of silver is preferably 70 wt % or more, more preferably 80 wt % or more, and still more preferably 90 wt % or more.

As metal powders, those appropriately produced may be used, or commercially available products may be used.

Examples of methods for producing a silver powder include a method for adding a reducing agent-containing aqueous solution to an aqueous reaction system containing silver ions to reduce and precipitate silver particles. In addition, a silver powder, such as a silver-coated copper powder, which has a silver surface and an interior composed of a metal other than silver may be used.

A metal powder includes a flake-shaped powder. Here, the term “flake-shaped powder” in the present specification refers to a powder (metal powder) with a thickness of 1/10 or less of the maximum particle diameter. Here, the maximum particle diameter of the flake-shaped powder is defined as follows. Each powder particle has different end-to-end lengths depending on directions in a plan view, and the longest of these lengths is taken as a maximum particle diameter. The maximum particle diameter can be determined through optical microscopic observation, scanning electron microscope (SEM) observation (for example, 5000x field of view), or the like.

When a metal powder is flake-shaped, it has top and bottom surfaces that spread in the surface direction, and therefore, the percentage of surface contact between metal powders is increased, leading to high conductivity (low resistivity).

In addition, as flake-shaped metal powders, those appropriately produced may be used, or commercially available products may be used.

Flake-shaped metal powders can be produced, for example, by preparing a thin film of a desired metal and then finely pulverizing the thin film. Since flake-shaped metal powders are obtained by finely pulverizing thin films through the production method, individual crushed metal pieces are also flattened. The thickness with respect to the particle diameter (that is, the degree of flattening) can be adjusted by adjusting the thickness of the thin films and the degree of fine pulverization.

The percentage of a flake-shaped powder in the metal powder is preferably 2.5 wt % or more, more preferably 5 wt % or more, and still more preferably 7.5 wt % or more. In addition, the percentage of the flake-shaped powder in the metal powder is preferably 50 wt % or less, more preferably 40 wt % or less, still more preferably 30 wt % or less, and even more preferably 25 wt % or less.

From the viewpoint of high conductivity (low resistivity), a higher proportion of the flake-shaped powder in the metal powder is preferable. However, if the proportion thereof is too high, the stretchability will decrease and the elongation at break will decrease. The degree of freedom of movement of the metal powder is necessary for smooth stretching and contracting of the stretchable electrical wiring 30A, but when the percentage of the flake-shaped powder exceeds 50 wt %, it is thought to be due to the fact that the flake shape itself has a high resistance to movement.

The average maximum particle diameter of the flake-shaped powder is preferably 3 μm to 10 μm.

This is because if the average maximum particle diameter is 3 μm or more, sufficiently high conductivity (low resistivity) due to the effect of surface contact between metal powders can be obtained, and if the average maximum particle diameter is 10 μm or less, sufficient stretchability will decrease and the elongation at break will decrease.

### (Elongation at Break)

The elongation at break of the stretchable electrical wiring 30A is 130% or more.

The elongation at break is preferably 150% or more, more preferably 200% or more, still more preferably 250% or more, and even more preferably 300% or more.

The elongation at break of the stretchable electrical wiring 30A can be increased by increasing the proportion of the resin in the stretchable electrical wiring 30A, but the increase in proportion of the resin leads to an increase in resistivity. Therefore, the elongation at break is adjusted as appropriate by adjusting the proportion of the resin according to the elongation at break and resistivity required for a stretchable device in which the stretchable electrical wiring 30A is used.

In the present specification, the term “elongation at break” is defined by {(length at break-length before pulling)/length before pulling}×100. Although the elongation at break can be measured in each of predetermined directions, it is regarded that in the expression “elongation at break of 150% or more” in the present specification, it is defined as the elongation at break in a direction where the elongation at break is greatest. If there is no anisotropy in the elongation at break, the elongation at break will be uniform in all directions, and if the anisotropy in the elongation at break is small, the elongation at break will have values close to each other in any directions.

### (Method for Measuring Elongation at Break)

First, an example of a method for preparing a sample will be described below.

A glass plate with a clean surface is prepared. Subsequently, a PET film is placed on top of the glass plate and the top side is taped. Subsequently, an applicator (for example, YA type, 75 mm, 152 μm, made by Yoshimitsu Seiki) is prepared and set. Subsequently, a stretchable electrical wiring paste in a container is stirred without introducing air. Subsequently, the stretchable electrical wiring paste is applied on the PET film. Subsequently, the applicator is then slid to spread the stretchable electrical wiring paste. Subsequently, after spreading the stretchable electrical wiring paste, the PET film and the glass plate are taped. Subsequently, after allowing it to stand for 3 minutes to 5 minutes, it is placed in a dryer that has been preheated to 90° C. to 100° C. and dried for 1 hour. The above-described process is used to obtain a sheet-like sample of the stretchable electrical wiring 30A with a thickness of 30 μm to 70 μm. The combined thickness of the PET film and the sheet-like sample of the stretchable electrical wiring 30A is about 150 μm.

The elongation at break can be measured as follows. Six strip-like measurement samples of 10 mm wide and 30 mm long are cut out from each sheet-like sample of the stretchable electrical wiring 30A. For each measurement sample, the elongation at break is calculated through a method shown below, and an average value thereof is taken as an elongation at break. A metal substrate is sandwiched between grip portions at the top and bottom of a measuring instrument, and each measurement sample is fixed with double-sided tape so that the measurement site is 10 mm wide and 10 mm long. The measurement sample is then pulled at a tensile speed of 10 mm/min using a tensile tester (for example, product name: Autograph AGS-5kNX, manufactured by Shimadzu Corporation). The length of each measurement sample at break is then measured, and the length before pulling, 10 mm, is subtracted from that length to calculate the elongation at break of each measurement sample. An average value thereof is taken as an elongation at break, and the elongation at break is calculated according to the above-described definition.

### (Resistivity Before Stretching and Contracting)

The resistivity before stretching and contracting (normal resistivity) of the stretchable electrical wiring 30A is 2×10⁻² [Ωmm] or less. The resistivity thereof is preferably 7×10⁻³ [Ωmm] or less, more preferably 6×10⁻³ [Ωmm] or less, and still more preferably 4×10⁻³ [Ωmm] or less.

The resistivity before stretching and contracting of the stretchable electrical wiring 30A can be decreased by increasing the proportion of the metal powder in the stretchable electrical wiring 30A, but the decrease in proportion of the resin in accordance with the increase in proportion of the metal powder leads to a decrease in elongation at break. Therefore, the resistivity before stretching and contracting is adjusted as appropriate by adjusting the proportion of the metal powder according to the elongation at break and resistivity required for a stretchable device in which the stretchable electrical wiring 30A is used.

### (Method for Measuring Resistance Value and Resistivity)

First, a sheet-like sample of the stretchable electrical wiring 30A is prepared through the method described above.

The resistivity before stretching and contracting can be measured as follows. Similarly to the measurement of an elongation at break, six strip-like measurement samples of 10 mm wide and 30 mm long are cut out from each sheet-like sample of the stretchable electrical wiring 30A. A metal substrate is sandwiched between grip portions at the top and bottom of a measuring instrument, and each measurement sample is fixed with double-sided tape so that the measurement site is 10 mm wide and 10 mm long. The resistance value of each measurement sample is measured in this condition. An average value thereof is taken as a resistance value R₀ before stretching and contracting. The resistance value for each elongation is measured each time during stretching while stretching the sample by moving the metal substrate by 1 mm each, and an average value of the six samples is taken as a resistance value R during stretching thereof.

Subsequently, the thickness of each sheet-like sample of the stretchable electrical wiring 30A is then measured as follows. Each sheet-like sample of the stretchable electrical wiring 30A is punched out in a circular shape. Subsequently, the sample is placed on a flat table, and a rectangular PET film with one side larger than the diameter of the circular sample is placed on the sample. The thickness of four corners of a rectangular PET film is measured by, for example, Digimicro ZC-101 (manufactured by Nikon Corporation), and an average thereof is taken as a thickness of the PET film. Next, the combined thickness of the sample and the PET film is measured at five points (top, bottom, left, right, and center), and the thickness of the PET film is subtracted from the average thickness to calculate the thickness t of the sample.

Next, the resistivity ρ₀(=R₀×(cross-sectional area/length)) is calculated from the above-described resistance value R₀ before stretching and contracting and the thickness t, width, and length of the sheet-like sample of the stretchable electrical wiring 30A.

In addition, the resistivity at each elongation is also similarly calculated from the resistance value at each elongation and the thickness t, width, and length of the sheet-like sample of the stretchable electrical wiring 30A using the formula for resistivity ρ(=R×(cross-sectional area/length)).

In the stretchable electrical wiring 30A according to the first aspect, the ratio (ρ₅₀/ρ₀) of a resistivity (ρ₅₀) at 50% elongation to a resistivity (ρ0) before stretching and contracting is preferably 7 or less, more preferably 6 or less, and still more preferably 5 or less. In addition, the ratio (ρ₁₀₀/ρ₅₀) of a resistivity (ρ₁₀₀) at 100% elongation to a resistivity (ρ₅₀) at 50% elongation is preferably 8 or less, more preferably 7 or less, still more preferably 6 or less, and even more preferably 5 or less.

The ratio (ρ₅₀/ρ₀) of a resistivity (ρ₅₀) at 50% elongation to a resistivity (ρ0) before stretching and contracting and the ratio (ρ₁₀₀/ρ₅₀) of a resistivity (ρ₁₀₀) at 100% elongation to a resistivity (ρ₅₀) at 50% elongation are both preferably 7 or less, more preferably 6 or less, and still more preferably 5 or less.

In the stretchable electrical wiring 30A according to the first aspect, the rate of change of the ratio (ρ₁₀₀/ρ₅₀) of a resistivity (ρ₁₀₀) at 100% elongation to a resistivity (ρ₅₀) at 50% elongation with respect to the ratio (ρ₅₀/ρ0) of a resistivity (ρ₅₀) at 50% elongation to a resistivity (ρ0) before stretching and contracting is preferably 140% or less, more preferably 80% or less, still more preferably 70% or less, even more preferably 60% or less, and even more preferably 50% or less.

In the stretchable electrical wiring 30A according to the first aspect, it is more preferable that the ratio (ρ₅₀/ρ₀) of a resistivity (ρ₅₀) at 50% elongation to a resistivity (ρ₀) before stretching and contracting and the ratio (ρ₁₀₀/ρ₅₀) of a resistivity (ρ₁₀₀) at 100% elongation to a resistivity (ρ₅₀) at 50% elongation be both 7 or less and that the rate of change of the ratio (ρ₁₀₀/ρ₅₀) of a resistivity (ρ₁₀₀) at 100% elongation to a resistivity (ρ₅₀) at 50% elongation with respect to the ratio (ρ₅₀/ρ₀) of a resistivity (ρ₅₀) at 50% elongation to a resistivity (ρ0) before stretching and contracting be 140% or less.

A stretchable electrical wiring according to a second aspect includes: a resin; and a metal powder, in which an elongation at break is 130% or more, a ratio (ρ₅₀/ρ₀) of a resistivity (ρ₅₀) at 50% elongation to a resistivity (ρ0) before stretching and contracting is 7 or less, the metal powder includes a flake-shaped powder, and a percentage of the resin is 8 wt % to 20 wt %. Descriptions of configurations common to the stretchable electrical wiring according to the first aspect will not be repeated.

Furthermore, the ratio (ρ₁₀₀/ρ₅₀) of a resistivity (ρ₁₀₀) at 100% elongation to a resistivity (ρ₅₀) at 50% elongation is preferably 8 or less.

In addition, the percentage of the resin in the stretchable electrical wiring is preferably 10 wt % or more. The percentage of the resin in the stretchable electrical wiring is preferably 18 wt % or less.

The smaller the change in resistivity when the stretchable electrical wiring is stretched, the more preferable it is.

The ratio (ρ₅₀/ρ₀) of a resistivity at 50% elongation to a resistivity before stretching and contracting is preferably 6 or less and more preferably 5 or less. In addition, the ratio (ρ₁₀₀/ρ₅₀) of a resistivity (ρ₁₀₀) at 100% elongation to a resistivity (ρ₅₀) at 50% elongation is more preferably 7 or less, still more preferably 6 or less, and even more preferably 5 or less.

In the stretchable electrical wiring according to the second aspect, the rate of change of the ratio (ρ₁₀₀/ρ₅₀) of a resistivity (ρ₁₀₀) at 100% elongation to a resistivity (ρ₅₀) at 50% elongation with respect to the ratio (ρ₅₀/ρ₀) of a resistivity (ρ₅₀) at 50% elongation to a resistivity (ρ0) before stretching and contracting is preferably 140% or less.

A stretchable electrical wiring of a third aspect includes: a resin; and a metal powder, in which an elongation at break is 130% or more, a rate of change of a ratio (ρ₁₀₀/ρ₅₀) of a resistivity (ρ₁₀₀) at 100% elongation to a resistivity (ρ₅₀) at 50% elongation with respect to a ratio (ρ₅₀/ρ₀) of a resistivity (ρ₅₀) at 50% elongation to a resistivity (ρ₀) before stretching and contracting is 140% or less, the metal powder includes a flake-shaped powder, and a percentage of the resin is 8 wt % to 20 wt %. Descriptions of configurations common to the stretchable electrical wiring according to the first aspect will not be repeated.

In addition, the percentage of the resin in the stretchable electrical wiring is preferably 10 wt % or more. The percentage of the resin in the stretchable electrical wiring is preferably 18 wt % or less.

Although the resistivity of the stretchable electrical wiring decreases as it stretches, the smaller the rate of the decrease, the more preferable it is. The rate of change (ratio (ρ₁₀₀/ρ₅₀)/ratio (ρ₅₀/ρ₀)) is preferably 80% or less, more preferably 70% or less, still more preferably 60% or less, and even more preferably 50% or less.

### (Method for Preparing Stretchable Electrical Wiring)

The stretchable electrical wirings of the first to third aspects can be produced through main steps: a (1) stretchable electrical wiring paste preparation step; a (2) stretchable electrical wiring paste application step; and a (3) drying and solidifying step. In other words, in the (1) stretchable electrical wiring paste preparation step, a metal powder is incorporated into a resin composition containing the above-described resin and solvent to prepare a stretchable electrical wiring paste. Subsequently, in the (2) stretchable electrical wiring paste application step, the stretchable electrical wiring paste is applied onto a base material (for example, a PET film). Thereafter, in the (3) drying and solidifying step, a stretchable electrical wiring 30A can be prepared by removing the solvent and drying and solidifying the stretchable wiring paste.

As a specific example of a resin composition (a resin and a solvent) for producing the stretchable electrical wiring 30A, similar to the stretchable substrate 10, there can be mentioned a resin composition containing a resin component (II) having a urethane bond and a group represented by General Formulae (11), (21), or (31) described above.

The resin component (II) has high solubility in solvents due to its composition. Therefore, the resin composition containing the resin component (II) also has high solubility in solvents.

Such a resin composition having high solubility can easily form a resin composition layer through printing on an object to be applied, for example, through various printing methods. Then, this resin composition layer is solidified by drying without being cured, whereby a stretchable electrical wiring can be produced. Such a technique is suitable for forming electrodes or wiring using the resin composition containing conductive components.

Such a resin composition having high solubility is used to form a stretchable electrical wiring having stretchability, and a stretchable device composed of the stretchable electrical wiring has the great advantage of suppressing damage during its stretching and contracting.

Factors that can cause damage to normal stretchable devices during stretching and contracting, from the viewpoint of materials, include (i) interface delamination and structural defects such as voids caused by contraction due to heat or curing reactions, (ii) uneven hardness caused by uneven composition, and (iii) degradation of materials over time caused by light exposure, oxidation, and the like.

Therefore, structural defects such as voids, and interface delamination, uneven composition, and degradation of materials over time can be suppressed, thereby preventing damage to the stretchable devices during stretching and contracting.

Although molding by thermal melting and cross-linking by thermosetting or photocuring reactions are commonly used to process stretchable substrates, there is a concern that the reliability of the stretchable devices will be lowered if even micromachining is considered due to the reasons (i) to (iii). In contrast, for example, if there is a resin that can be molded only through applying and drying a resin composition in response to a lamination process, it is expected that favorable results can be obtained.

The stretchable electrical wiring can be obtained by preparing a stretchable electrical wiring paste by incorporating a metal powder into the resin composition of the above-described specific example, applying the stretchable electrical wiring paste to a substrate, and then solidifying it through drying.

The stretchable electrical wiring has favorable stretchability because it contains the resin component (II) as its main component. When the resin (b) is used, the stretchable electrical wiring further has moderate water repellency, which suppresses degradation over time caused by hydrolysis. The stretchable electrical wiring with such characteristics is particularly suitable for constructing various types of stretchable devices including wearable devices.

The stretchable electrical wiring can be formed simply by solidifying the resin composition through drying, as described above, without any curing reaction.

Therefore, it does not have the defects associated with performing a curing reaction.

For example, a photocuring reaction is significantly difficult to uniformly cure materials that do not transmit ultraviolet light. For example, when the periphery of a mounted device or an electronic component is irradiated with ultraviolet light, the degree of curing may vary in some areas in a photocurable stretchable electrical wiring due to variations in ultraviolet light transmission, and the stretchable electrical wiring is easily damaged in areas with low cross-linking density. In addition, non-cross-linked areas are easily degraded by oxidation.

On the other hand, a thermosetting reaction easily causes contraction differences in the stretchable electrical wiring due to heat distribution during curing. When such contraction differences occur, different constituent materials among devices, sealants, and the like are easily delaminated at these interfaces. In addition, if areas with different degrees of curing are created in the stretchable electrical wiring due to heat distribution, the stretchable electrical wiring will be easily degraded due to repeated stretching and contracting.

Furthermore, in both cases of photocuring and thermosetting reactions, it is difficult for the reactions to progress uniformly in the stretchable electrical wiring. In such cases, variations in composition and degree of curing occur in the stretchable electrical wiring, and the cured stretchable electrical wiring does not have desired stretchability and strength. In addition, because a curing agent is incorporated, degradation over time due to heat or light easily occurs.

In contrast, the stretchable electrical wiring obtained by solidifying the stretchable electrical wiring paste containing the resin composition of the above-described specific example through drying does not have such defects.

The stretchable electrical wiring can be produced without a curing reaction by, for example, applying the stretchable electrical wiring paste to a desired site and solidifying it through drying.

The stretchable electrical wiring paste can be applied, for example, through well-known methods using various coaters, wire bars, or the like, or through various printing methods including inkjet printing methods.

During the production of the stretchable electrical wiring, the drying temperature of the stretchable electrical wiring paste is preferably 25° C. to 150° C. and more preferably 25° C. to 120° C. When the drying temperature is 25° C. or higher, it is possible to more efficiently produce the stretchable electrical wiring. When the drying temperature is 150° C. or lower, the drying temperature is suppressed from becoming excessively high, deformation of a release sheet and damage to the stretchable electrical wiring are less likely to occur, and deterioration of the stretchable electrical wiring is suppressed.

The drying time of the stretchable electrical wiring paste during the production of the stretchable electrical wiring may be set appropriately according to the drying temperature, but is preferably 10 minutes to 120 minutes and more preferably 30 minutes to 90 minutes. When the drying time is within these ranges, stretchable electrical wiring with favorable characteristics can be efficiently produced.

Completion of solidification of the stretchable electrical wiring paste through drying (formation of the stretchable electrical wiring) can be confirmed, for example, by the fact that no clear change in mass of the resin composition being subjected to drying can be observed.

The thickness of the stretchable electrical wiring is not particularly limited, but can be, for example, 10 μm to 5,000 μm.

### <Second Electrical Wiring>

Similarly to the first electrical wiring 30A, the second electrical wiring 30B can be made of an electrical wiring material having stretchability. In this case, it is preferable that the same conductive material as the stretchable material of the second electrical wiring 30B be used. For example, a stretchable resin material containing a flake-shaped metal powder can be used as the material for the first electrical wiring 30A and the second electrical wiring 30B.

### <Conductive Adhesive>

In the conductive adhesive 40 containing a stretchable resin, a stretchable resin containing a metal powder (stretchable resin) can be used. In addition, well-known solder materials may be used.

The material of the stretchable resin-containing conductive adhesive 40 may be electrical wiring material having stretchability. For example, a stretchable resin material containing a metal powder (for example, a flake-shaped metal powder) can be used. In this case, by changing the content ratio between the stretchable resin and the metal powder, for example, by increasing the content ratio of the metal powder, the conductivity of the stretchable resin-containing conductive adhesive 40 can be made higher than that of the first electrical wiring 30A, or conversely, by increasing the content ratio of the stretchable resin, the stretchability of the stretchable resin-containing conductive adhesive 40 can be made higher than that of the first electrical wiring 30A. [Stretchable device]

A stretchable device according to one embodiment has a configuration in which an electronic component is disposed on a non-stretchable portion included in the above-described stretchable circuit substrate.

Here, the term “electronic component” is not particularly limited as long as it can be installed on a non-stretchable portion, and well-known electronic components can be used. Examples thereof include various sensors, capacitors, inductors, high frequency filters, transformers, resistors, varistors, diodes, various ICs, and various actuators.

In addition, a stretchable device according to another embodiment has a configuration in which a module is disposed on a non-stretchable portion included in the above-described stretchable circuit substrate.

Here, the term “module” is not particularly limited as long as it can be installed on a non-stretchable portion, and well-known modules can be used. Examples thereof include a sensor module including various sensors, a wireless communication unit, and a battery, and DC/DC converters.

In addition, a stretchable device according to still another embodiment has a configuration in which a battery is disposed on a non-stretchable portion included in the above-described stretchable circuit substrate.

Here, the term “battery” is not particularly limited as long as it can be installed on a non-stretchable portion, and well-known batteries can be used. Examples thereof include various solar cells, lithium ion batteries, and electric double layer capacitors.

Examples of solar cells from the viewpoint of electrode arrangement include double-sided electrode solar cells and back-side electrode solar cells. In addition, examples thereof from the viewpoint of materials include inorganic material-based solar cells such as silicon-based solar cells and compound semiconductor-based solar cells, and organic solar cells.

### EXAMPLES

Hereinafter, the present invention will be described in more detail. However, the present invention is not limited to the examples shown below. Hereinafter, experimental examples will be shown in which the characteristics of the first electrical wiring having stretchability, included in the stretchable circuit substrate according to the present invention, were examined using specific materials.

Raw materials used in preparation of a stretchable electrical wiring paste are shown below.

### Resin (a)

(a)-1: Urethane acrylate oligomer (product name: UN-5500, manufactured by Negami Chemical Industrial Co., Ltd.)

### Resin (b)

(b)-1: Methacrylate-modified polydimethylsiloxane modified with a methacryloyl group at a single terminal (product name: Silaplane (registered trademark) FM-0721, manufactured by JNC Corporation)

### Polymerization Initiator (c)

(c)-1: Dimethyl 2,2′-azobis(2-methylpropionate), azo polymerization initiator (product name: V601, manufactured by FUJIFILM Wako Pure Chemical Corporation)

### RAFT Agent

(1)-1: RAFT agent represented by Formula (1)-1 below (manufactured by FUJIFILM Wako Pure Chemical Corporation)
(3)-1: RAFT agent represented by Formula (3)-1 below (manufactured by FUJIFILM Wako Pure Chemical Corporation)·

### Other Polymerizable Components

MMA: Methyl methacrylate

### Solvent

BCA: Butyl carbitol acetate
   Metal powder
Silver powder (percentage of flake-shaped powder: 12.5 [wt %], average maximum particle diameter: 3 μm)

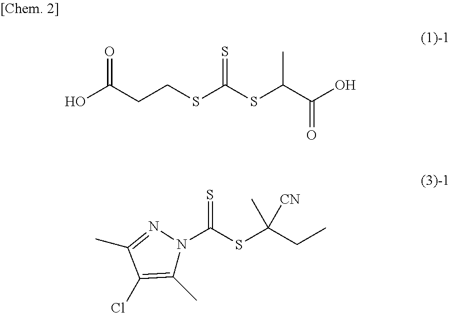 [SMILES: CC(SC(=S)SCCC(=O)O)C(=O)O ; CCC(C)(C#N)SC(=S)n1nc(C)c(Cl)c1C]

### Experimental Example 1

A resin (a)-1, a polymerization initiator (c)-1, a RAFT agent (1)-1, a silver powder, and BCA were weighed out in a flask and mixed together using a stirrer at normal temperature to obtain a stretchable electrical wiring paste.

The formulation amounts of resin (b), polymerization initiator (c), and RAFT agent were determined so that the percentage of urethane bonds in the resins in the resulting stretchable electrical wiring was 20 wt % based on 100 parts by mass of the resin (a). In addition, the formulation amount of silver powder was determined so that the percentage of the resins in the resulting stretchable electrical wiring was 5 wt %. In other words, the formulation amount of silver powder was determined so that the ratio of the resins to the silver powder was 8 wt %: 92 wt %.

Subsequently, sheet-like samples of stretchable electrical wirings were prepared through the above-described method, and an elongation at break, a resistivity (ρ₀) before stretching and contracting, a resistivity (ρ₅₀) at 50% elongation, and a resistivity (ρ₁₀₀) at 100% elongation were measured. The obtained results are shown in Table 1.

TABLE 1

| | | | Metal | | | | | |
|---|---|---|---|---|---|---|---|---|
| | Resin | | powder | | Resistivity | | | |
| | Percentage | Percentage | Percentage | | (Rdc) before | | | Rate of |
| | of resin in | of urethane | of | | stretching | | | change of |
| | wiring | bond in | flake-shaped | Elongation | and | | | (ρ₅₀/ρ₀) with |
| | material | resin | powder | at break | contracting | | | respect to |
| | [wt %] | [%] | wt % | [%] | [Ω cm] | ρ₅₀/ρ₀ | ρ₁₀₀/ρ₅₀ | (ρ₅₀/ρ₀) (%) |
| Comparative | 6 | 20 | 12.5 | 5.3 | 8.60*10\hat{ }(−3) | — | — | — |
| Example 1 | | | | | | | | |
| Example 1 | 8 | 20 | 12.5 | 130.0 | 2.81*10\hat{ }(−3) | 5.3 | 8.0 | 51% |
| Example 2 | 10 | 20 | 12.5 | 165.3 | 4.28*10\hat{ }(−3) | 4.0 | 4.5 | 13% |
| Example 3 | 15 | 20 | 12.5 | 322.1 | 4.64*10\hat{ }(−3) | 5.3 | 5.4 | 0% |
| Example 4 | 18 | 20 | 12.5 | 370.8 | 3.00*10\hat{ }(−3) | 2.9 | 5.2 | 82% |
| Example 5 | 20 | 20 | 12.5 | 414.9 | 1.53*10\hat{ }(−2) | 1.7 | 4.0 | 133% |
| Comparative | 22 | 20 | 12.5 | 482 | 2.89*10\hat{ }(−1) | 0.012 | 4.4 | 36030% |
| Example 2 | | | | | | | | |
| Comparative | 15 | 0 | 12.5 | 6.0 | 3.59*10\hat{ }(−1) | — | — | — |
| Example 3 | | | | | | | | |
| Comparative | 15 | 10 | 12.5 | 7.0 | 1.13*10\hat{ }(−2) | — | — | — |
| Example 4 | | | | | | | | |
| Comparative | 15 | 15 | 12.5 | 37.4 | 6.48*10\hat{ }(−3) | — | — | — |
| Example 5 | | | | | | | | |
| Example 6 | 15 | 17.5 | 12.5 | 172.3 | 7.34*10\hat{ }(−3) | 3.3 | 4.1 | 25% |
| Example 3 | 15 | 20 | 12.5 | 322.1 | 4.64*10\hat{ }(−3) | 5.3 | 5.4 | 0% |
| Example 7 | 15 | 22 | 12.5 | 297.1 | 6.61*10\hat{ }(−3) | 5.0 | 5.35 | 7% |
| Example 8 | 15 | 25 | 12.5 | 245.5 | 4.75*10\hat{ }(−3) | 2.8 | 4.9 | 75% |
| Example 9 | 15 | 30 | 12.5 | 130.4 | 3.29*10\hat{ }(−3) | 5.0 | — | — |
| Comparative | 15 | 30 | 0 | 47.2 | 4.71*10\hat{ }(−1) | — | — | — |
| Example 6 | | | | | | | | |
| Comparative | 15 | 30 | 12.5 | 8.9 | 1.93*10\hat{ }(−3) | — | — | — |
| Example 7 | | | | | | | | |
| Example 10 | 15 | 20 | 2.5 | 322.1 | 4.72*10\hat{ }(−3) | 3.3 | 4.2 | 27% |
| Example 11 | 15 | 20 | 7.5 | 275.9 | 4.77*10\hat{ }(−3) | 2.8 | 3.9 | 42% |
| Example 3 | 15 | 20 | 12.5 | 322.1 | 4.64*10\hat{ }(−3) | 5.3 | 5.4 | 0% |
| Example 12 | 15 | 20 | 30 | 300 | 4.76*10\hat{ }(−3) | 4.0 | 6.9 | 73% |
| Example 13 | 15 | 20 | 40 | 230.5 | 5.62*10\hat{ }(−3) | 2.2 | 5.10 | 131% |
| Example 14 | 15 | 20 | 50 | 169.3 | 2.66*10\hat{ }(−3) | 51 | — | — |

### Experimental Examples 2 to 5 and Comparative Examples 1 and 2

For Experimental Examples 2 to 5 and Comparative Examples 1 and 2, sheet-like samples of stretchable electrical wirings were prepared in the same manner as in Experimental Example 1 except that the formulation amount of silver powder was adjusted so that the percentage of resins in each resulting stretchable electrical wiring was 10 wt %, 15 wt %, 18 wt %, 20 wt %, 6 wt %, and 22 wt %. The same characteristics were measured on the resulting samples. The results are shown in Table 1.

### Experimental Examples 6 to 9 and Comparative Examples 3 to 5

For all of Experimental Examples 6 to 9 and Comparative Examples 3 to 5, sheet-like samples of stretchable electrical wirings were prepared in the same manner as in Experimental Example 1 except that the formulation amount was adjusted so that the percentage of resins in each resulting stretchable electrical wiring was 15 wt % and the percentage of urethane bonds in the resins in each resulting stretchable electrical wiring was 17.5 wt %, 20 wt %, 22 wt %, 25 wt %, 30 wt %, 0 wt %, 10 wt %, and 15 wt %. The same characteristics were measured on the resulting samples. The results are shown in Table 1.

### Comparative Examples 6 and 7

Comparative Examples 6 and 7 are those in which each stretchable electrical wiring paste was applied and then subjected to a curing reaction instead of drying and solidifying. In Comparative Example 6, a stretchable electrical wiring paste was obtained in the same manner as in Comparative Example 5 except that a silver powder did not have a flake shape. In Comparative Example 7, the same stretchable electrical wiring paste as in Experimental Example 9 was used. The same characteristics were measured on the resulting samples. The results are shown in Table 1.

### Experimental Examples 10 to 16

For all of Experimental Examples 10 to 16, sheet-like samples of stretchable electrical wirings were prepared in the same manner as in Experimental Example 1 except that the percentage of resins in each resulting stretchable electrical wiring was 15 wt %, the percentage of urethane bonds in the resins in each resulting stretchable electrical wiring was 20 mol %, and a silver powder in which the percentage of each flake-shaped powder was 2.5 wt %, 7.5 wt %, 12.5 wt %, 30 wt %, 40 wt %, and 50 wt % was used.

The same characteristics were measured on the resulting samples. The results are shown in Table 1.

Findings obtained from the results of Table 1 will be shown. Values not included in Table 1 are those that could not be measured or were not measured.

Experimental Examples 1 to 6 and Comparative Examples 1 and 2 will be compared with each other. When the percentage of urethane bonds in resins and the percentage of a flake-shaped powder were fixed to the percentages shown in Table 1, the following findings were obtained.

When the percentage of resins in stretchable electrical wiring was 8 wt % (resin:silver powder=8:92) or more, the elongation at break was 130% or more, and the higher the percentage of the resins, the higher the elongation at break was obtained. On the other hand, when the percentage of resins was 20 wt % or more, the resistivity before stretching and contracting was 1×10⁻² [Ωcm] or more. From the viewpoint of achieving both a higher elongation at break (150% or more) and a lower resistivity before stretching and contracting (5×10⁻³ [Ωcm] or less), the percentage of resins in stretchable electrical wiring is preferably 10 wt % to 18 wt %.

In addition, when the percentage of resins was 20 wt % (resin:silver powder=20:80) (Experimental Example 5), the resistivity before stretching and contracting was 1.53×10⁻² [Ωcm] which was slightly high. However, reflecting its high elongation at break, the ratio (ρ₅₀/ρ₀) of a resistivity (ρ₅₀) at 50% elongation to a resistivity (ρ₀) before stretching and contracting was 1.7 which was a low rate of change and the ratio (ρ₁₀₀/ρ₅₀) of a resistivity (ρ₁₀₀) at 100% elongation to a resistivity (ρ₅₀) at 50% elongation was 4.0 which was a sufficiently low rate of change. From the viewpoint of achieving both the high elongation at break (150% or more) and low ratios (ρ₅₀/ρ₀) and (ρ₁₀₀/ρ₅₀), the percentage of resins in stretchable electrical wiring is preferably 10 wt % to 20 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of resins in stretchable electrical wiring is preferably 10 wt % to 15 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of resins in stretchable electrical wiring is preferably 10 wt % to 15 wt %.

Next, Experimental Examples 3, 6 to 9 and Comparative Examples 3 and 4 will be compared with each other. When the percentage of resins in stretchable electrical wiring and the percentage of a flake-shaped powder were fixed to the percentages shown in Table 1, the following findings were obtained.

When the percentage of urethane bonds in resins was 15 wt % or less, the elongation at break was 40% or less. On the other hand, when the percentage of urethane bonds was 25 wt % (Experimental Example 8), the elongation at break was 245.5%, but when the percentage thereof was 30 wt % (Experimental Example 9), the elongation at break was 130.4%. From the viewpoint of a high elongation at break (150% or more), the percentage of urethane bonds in resins is preferably 17.5 wt % to 25 wt %. In addition, from the viewpoint of achieving both a higher elongation at break (150% or more) and a lower resistivity before stretching and contracting (7×10⁻³ [Ωcm] or less), the percentage of urethane bonds in resins is preferably 20 wt % to 25 wt %.

In addition, from the viewpoint of achieving both the high elongation at break (150% or more) and low ratios (ρ₅₀/ρ₀) and (ρ₁₀₀/ρ₅₀), the percentage of urethane bonds in resins is preferably 17.5 wt % to 25 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of urethane bonds in resins is preferably 17.5 wt % to 22 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of urethane bonds in resins is preferably 17.5 wt % to 22 wt %.

In Comparative Examples 6 and 7, each stretchable electrical wiring paste was applied and then subjected to a curing reaction instead of drying and solidifying. However, the resistivity before stretching and contracting in Comparative Example 6 in which a silver powder did not have a flake shape was about 5×10⁻¹ [Ωcm] which was considerably high, and the elongation at break in Comparative Example 7 of which the composition of the stretchable electrical wiring paste itself was the same as that of Experimental Example 9 was 10% or less. Therefore, it was found that Comparative Examples 6 and 7 were not suitable for application to stretchable devices.

Next, Experimental Examples 3, 10 to 14 will be compared with each other. When the percentage of resins in stretchable electrical wiring and the percentage of urethane bonds in the resins were fixed to the percentages shown in Table 1, the following findings were obtained.

As the percentage of a flake-shaped powder in a silver powder was 40 wt % or 50 wt %, the elongation at break was negatively affected and gradually decreased. Furthermore, at 40 wt % (Experimental Example 13), the rate of change of the ratio (ρ₁₀₀/ρ₅₀) to the (ρ₅₀/ρ₀) increased to 130% or more, and at 50 wt % (Experimental Example 14), the ratio (ρ₅₀/ρ₀) was 51 times greater.

From a viewpoint, when the percentage of a flake-shaped powder in a silver powder is within a range of 2.5 wt % to 50 wt %, it is possible to achieve both a higher elongation at break (150% or more) and a lower resistivity before stretching and contracting 7×10⁻³ [(2 cm] or less).

From the viewpoint of achieving both the high elongation at break (150% or more) and low ratios (ρ₅₀/ρ₀) and (ρ₁₀₀/ρ₅₀), the percentage of a flake-shaped powder in a silver powder is preferably 2.5 wt % to 40 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of a flake-shaped powder in a silver powder is preferably 2.5 wt % to 12.5 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of a flake-shaped powder in a silver powder is preferably 2.5 wt % to 12.5 wt %.

High flexibility is obtained by containing urethane bonds in resins. In addition, when resins contain either urethane bonds or siloxane bonds, both high stretchability and low resistivity can be achieved through an effect of improving dispersion and aggregation of a silver powder. Furthermore, when both the urethane bonds and the siloxane bonds are contained, a higher improvement effect is obtained.

### REFERENCE SIGNS LIST

10 Stretchable substrate
20 Non-stretchable portion
30A First electrical wiring
30B Second electrical wiring
40 Conductive adhesive
100, 200 Stretchable circuit substrate

1. A stretchable circuit substrate comprising:
a stretchable substrate;
a non-stretchable portion connected to at least a part of the outer circumferential portion of a first surface of the stretchable substrate or a side surface portion of the stretchable substrate;
a first electrical wiring having stretchability and disposed on the first surface of the stretchable substrate; and
a second electrical wiring disposed on the non-stretchable portion,
wherein at least a part of the first electrical wiring and the second electrical wiring are connected.

2. The stretchable circuit substrate according to claim 1,
wherein the stretchable substrate and the non-stretchable portion are connected by a conductive adhesive containing a stretchable resin.

3. The stretchable circuit substrate according to claim 1,
wherein a part of the non-stretchable portion has a tab portion protruding upward.

4. The stretchable circuit substrate according to claim 1,
wherein the non-stretchable portion is disposed on the outer circumferential portion of the stretchable substrate.

5. The stretchable circuit substrate according to claim 1,
wherein the non-stretchable portion is connected to the side surface portion of the stretchable substrate, and the bottom surface of the non-stretchable portion and the bottom surface of the stretchable substrate are disposed flush with each other.

6. The stretchable circuit substrate according to claim 1,
wherein a seal for attaching to an adherend is provided on the surface on the rear side of the first surface of the stretchable circuit substrate.

7. A stretchable device comprising:
an electronic component disposed on the non-stretchable portion included in the stretchable circuit substrate according to claim 1.

8. A stretchable device comprising:
a module disposed on the non-stretchable portion included in the stretchable circuit substrate according to claim 1.

9. A stretchable device comprising:
a battery disposed on the non-stretchable portion included in the stretchable circuit substrate according to claim 1.

10. The stretchable circuit substrate according to claim 2,
wherein a part of the non-stretchable portion has a tab portion protruding upward.

11. The stretchable circuit substrate according to claim 2,
wherein the non-stretchable portion is disposed on the outer circumferential portion of the stretchable substrate.

12. The stretchable circuit substrate according to claim 2,
wherein the non-stretchable portion is connected to the side surface portion of the stretchable substrate, and the bottom surface of the non-stretchable portion and the bottom surface of the stretchable substrate are disposed flush with each other.

13. The stretchable circuit substrate according to claim 2,
wherein a seal for attaching to an adherend is provided on the surface on the rear side of the first surface of the stretchable circuit substrate.

14. A stretchable device comprising:
an electronic component disposed on the non-stretchable portion included in the stretchable circuit substrate according to claim 2.

15. A stretchable device comprising:
a module disposed on the non-stretchable portion included in the stretchable circuit substrate according to claim 2.

16. A stretchable device comprising:
a battery disposed on the non-stretchable portion included in the stretchable circuit substrate according to claim 2.
